(19) United States
(12) Patent Application Publication
(10) Pub. No.: US 2007/0127300 A1
(43) Pub. Date: Jun. 7, 2007

(54) Bun-in test method semiconductor memory device

(75) Inventors: Woo-Jin Kim, Pyeongtaek-si (KR); Kwang-Joon Park, Cheonan-si (KR); Joo-Seok Kwak, Cheonan-si (KR); Kwang-Won Lee, Cheonan-si (KR); Jong-Jin Yi, Cheonan-si (KR)

Correspondence Address: LEE & MORSE, P.C., 3141 FAIRVIEW PARK DRIVE, SUITE 500, FALLS CHURCH, VA, 22042, US

(73) Assignee: SAMSUNG ELECTRONICS CO., LTD., Suwon-si (KR)

(21) Appl. No.: 11/647,398

(22) Filed: Dec. 29, 2006

Related U.S. Application Data
(62) Division of application No. 11/020,323, filed on Dec. 27, 2004.

(30) Foreign Application Priority Data
Jun. 14, 2004 (KR) 2004-43531

(51) Int. Cl. G11C 29/00

(52) U.S. Cl. 365/201

(57) ABSTRACT

A semiconductor memory device includes a switch circuit that inverts input data or output data when burn-in mode enable signals are activated or a control signal switch that inverts external control signals or internal control signals when burn-in mode enable signals are activated. A burn-in test method for the semiconductor memory device performs a pass/fail decision to determine whether the output data has passed or failed based on an inverted logical value of the input data.

### CROSS REFERENCE TO RELATED APPLICATION(S)

This is a divisional application based on pending application Ser. No. 11/020,323, filed Dec. 27, 2004, the entire contents of which is hereby incorporated by reference.

### BACKGROUND OF THE INVENTION

1. Field of the Invention

The present invention generally relates to a semiconductor integrated circuit device. More particularly, the present invention relates to a semiconductor memory device and a burn-in test method therefor.

2. Description of the Related Art

Potential defects may occur to a semiconductor device during either fabrication or assembly. Most potentially defective devices may break down within approximately one thousand hours after initial use. For this reason, final device products are generally subjected to a burn-in test before sale.

In the burn-in test, the devices undergo extreme electrical and thermal stress for an extended time, so that defective devices may be screened in advance. For example, the burn-in test for a memory device is performed at relatively higher voltage and temperature than is experienced during normal operation, such as 5 V and 125° C., to apply electrical and thermal stress to the device.

In general, the burn-in test for a memory device is performed at a wafer level or package level using a burn-in test apparatus. For the burn-in test, the memory has a burn-in mode generator therein. The burn-in mode generator converts a normal operation mode into a burn-in mode in the memory device.

FIG. 1 is a block diagram schematically illustrating a structure of a conventional memory device.

As shown in FIG. 1, the conventional memory device 100 includes a memory cell array 107, an address control unit 110, an internal voltage generating unit 120, a burn-in (BI) mode generator 130, a data input unit 140, a data output unit 150, a control signal generator 160, and a memory input/output control circuit 170.

The memory cell array 107 has a large number of memory cells arranged in rows and columns as in a matrix.

The address control unit 110 includes an address control circuit 111, a column selection circuit 112, and a row selection circuit 113. The address control circuit 111 receives external address signals (A0˜Ai) and then outputs column address signals and row address signals to the column selection circuit 112 and the row selection circuit 113, respectively, under the control of internal control signals (ZCTRL) produced in the control signal generator 160. The column selection circuit 112 and the row selection circuit 113 decode the column address signals and the row address signals, respectively, and then select a specific column line, e.g., a bit line, and a specific row line, e.g., a word line, in the memory cell array 107.

The internal voltage generating unit 120 includes a reference voltage generator 121 and an internal voltage generator 122. The reference voltage generator 121 receives a voltage (Vcc) and generates a reference voltage (Vref) in the memory device 100. The internal voltage generator 122 generates an internal voltage (Vint) applied to the memory cell array 107.

The burn-in mode generator 130 receives external control signals (/CTRL), such as chip select signals (/CS), write enable signal (/WE), out enable signals (/OE) and other signals (/OTHRS). Then, the burn-in mode generator 130 synchronizes and combines the external control signals (/CTRL) and thereby activates burn-in mode enable signals (ZBIE).

FIG. 2 is a graph illustrating a relation between an internal voltage and an external voltage.

Referring to FIGS. 1 and 2, in a case of a normal operation state, in which the burn-in mode generator 130 does not activate burn-in mode enable signals (ZBIE), the memory device 100 is in a normal operation mode (N), in which the internal voltage generator 122 applies a uniform internal voltage (Vint1) to the memory cell array 107 when an external voltage (Vext) is above the smallest voltage (Vs) necessary for device operation. However, in a case of a burn-in state, in which the burn-in mode generator 130 outputs activated burn-in mode enable signals (ZBIE) to the internal voltage generator 122, the memory device 100 is in a burn-in mode (B), in which the internal voltage generator 122 applies an internal voltage, rising in proportion to a rise in an external voltage, to the memory cell array 107.

Returning to FIG. 1, the data input unit 140 includes a data input buffer 141 and a data input register 142. The data input buffer 141 receives data from data input/output terminals (DQ) and then outputs data synchronized with clock signals (CLK) to the data input register 142. The data input register 142 outputs synchronized data to a selected memory cell of the memory cell array 107.

The data output unit 150 includes a sens amp (not shown), a data output register 151, and a data output buffer 152. The sens amp amplifies data in the memory cell array 107. The data output register 151 receives amplified data and then outputs it to the data output buffer 152. The data output buffer 152 activates amplified data under the control of internal output enable signals and outputs it to the data input/output terminals (DQ).

The control signal generator 160 receives the burn-in mode enable signals (ZBIE) as well as external control signals (/CTRL), such as chip select signals (/CS), write enable signal (/WE), out enable signals (/OE) and other signals (/OTHRS). The control signal generator 160 then outputs internal control signals (ZCTRL), such as internal chip select signals (ZCS), internal input enable signals (ZWE) and internal output enable signals (OEM).

The memory input/output control circuit 170 determines, by receiving the internal control signals (ZCTRL), whether an operation state of the memory cell array 107 is a write state or a read state, and then outputs a specific signal to the memory cell array 107.

FIG. 3 is a flow chart schematically illustrating a conventional burn-in test method for a memory device.

Referring to FIG. 3, initially, in step S11, the memory device is loaded into a burn-in test apparatus. In step S12, a burn-in program suitable for the burn-in test is loaded into the apparatus. In step S13, a contact check is performed to ascertain whether the memory device is properly loaded and whether the burn-in program is fit for the loaded memory device. In step S14, a write data operation for each memory cell of the memory device is performed, and then, in step S15, a read data operation for each memory cell is performed.

Thereafter, in step S16, a pass/fail decision is performed to determine whether the memory cells have passed or failed.

FIG. 4 is a diagram schematically illustrating a write and read data procedure in the conventional burn-in test method described above. In FIG. 4, (m, n) represents an m-th row and an n-th column of the memory cell array. Rows and columns may correspond to word lines and bit lines, respectively, of the memory cell array, but not necessarily to the same word line or bit line. Although FIG. 4 illustrates a write data and read data procedure performed in an order of (1, 1), (1, 2), (1, 3), . . . , another order such as (1, 1), (2, 1), (3, 1), . . . may be possible.

As shown in FIG. 4, if data “1 ” is written during the write data step, i.e., step S14, and then data “1 ” is read during the read data step, i.e., step S15, the corresponding memory cell, e.g., cell (1, 1) is determined to have passed (P). But, if data “1 ” is written and then data “0 ” is read, the corresponding memory cell, e.g., cell (1,3), is determined to have failed (F). Similarly, if write data is “0 ” and read data is also “0 ”, the corresponding memory cell is determined to have passed (P). But, if write data is “0 ” and read data is “1 ”, the corresponding memory cell is determined to have failed (F).

Returning to FIG. 3, after the pass/fail decision, in step S17, the burn-in program is unloaded from the apparatus, and then, in step S18, the memory device is also unloaded.

Disadvantageously, in the above-described burn-in test method, it is not possible to determine whether the memory device is in the burn-in mode or the normal operation mode. All the contact check in the aforementioned step S13 is able to do is ascertain whether the memory device is properly loaded and whether the burn-in program is fit for the loaded memory device.

This disadvantage may cause the following problem. The burn-in mode generator 130, shown in FIG. 1, combines the external control signals (/CTRL) and then activates the burn-in mode enable signals (ZBIE), as described above. However, the burn-in mode generator 130 may sometimes fail to activate the burn-in mode enable signals (ZBIE) by making errors in perceiving the external control signals (/CTRL) due to an influence of noise, for example, or other interference. So, although the memory device is in the normal operation mode, a working engineer may incorrectly believe that the device is in the burn-in mode. In this circumstance, when the working engineer applies a specific external voltage (Vext1) to the device in order to provide a prescribed internal voltage (Vint2) as shown in FIG. 2, an internal voltage actually applied to the memory cell array is merely a relatively lower voltage (Vint1), not the prescribed voltage (Vint2). Therefore, the burn-in test is unreliably performed at the lower voltage (Vint1), and may fail to screen potentially defective devices.

### SUMMARY OF THE INVENTION

The present invention is therefore directed to a semiconductor memory device and a burn-in test method therefor, which substantially overcome one or more of the problems due to the limitations and disadvantages of the related art.

It is a feature of an embodiment of the present invention to provide a memory device and a related burn-in test method, which are able to determine whether the memory device is in a burn-in mode.

At least the above or other features and advantages of the present invention may be realized by providing a semiconductor memory device including a memory cell array having memory cells arranged in rows and columns, an address control unit for selecting one of the rows and columns, a burn-in mode generator for receiving external control signals and for generating burn-in mode enable signals, an internal voltage generating unit for applying an internal voltage in a burn-in mode to the memory cell array when the burn-in mode enable signals are activated, a data input unit for inputting data to the memory cell array, and a data output unit for outputting data from the memory cell array, wherein the data input unit includes a first data switch circuit that is operable to invert logical values of the input data based on whether the burn-in mode enable signals are activated.

At least the above or other features and advantages of the present invention may be realized by providing a semiconductor memory device including a memory cell array having memory cells arranged in rows and columns, an address control unit for selecting one of the rows and columns, a burn-in mode generator for receiving external control signals and for generating burn-in mode enable signals, an internal voltage generating unit for applying an internal voltage in a burn-in mode to the memory cell array when the burn-in mode enable signals are activated, a data input unit for inputting data to the memory cell array, and a data output unit for outputting data from the memory cell array, wherein the data output unit includes a second data switch circuit that inverts logical values of the output data based on whether the burn-in mode enable signals are activated.

In the above memory devices, the first or the second data switch circuit may invert the logical values of the input or the output data, respectively, when the burn-in mode enable signals are activated.

Furthermore, the first or the second data switch circuit may include a first CMOS transistor having a first pMOS transistor controlled by the burn-in mode enable signals and a first nMOS transistor controlled by the inverted signals of the burn-in mode enable signals, and a second CMOS transistor having a second nMOS transistor controlled by the burn-in mode enable signals and a second pMOS transistor controlled by the inverted signals of the burn-in mode enable signals.

At least the above and other features and advantages of the present invention may be realized by providing a semiconductor memory device including a memory cell array having memory cells arranged in rows and columns, an address control unit for selecting one of the rows and columns, a burn-in mode generator for receiving external control signals and for generating burn-in mode enable signals, an internal voltage generating unit for applying an internal voltage in a burn-in mode to the memory cell array when the burn-in mode enable signals are activated, a data input unit for inputting data to the memory cell array, a data output unit for outputting data from the memory cell array, a control signal generator for receiving the external control signals and for generating internal control signals, a memory input/output control circuit for receiving the internal control signals and for specifying whether an operation state of the memory cell array is a write state or a read state, and a control signal switch circuit for inverting the external control signals or the internal control signals based on whether the burn-in mode enable signals are activated.

In the above memory device, the control signal switch circuit may invert the external control signals or the internal control signals when the burn-in mode enable signals are activated.

Furthermore, the control signal switch circuit may include a third CMOS transistor having a third pMOS transistor controlled by the burn-in mode enable signals and a third nMOS transistor controlled by the inverted signals of the burn-in mode enable signals, a fourth CMOS transistor having a fourth nMOS transistor controlled by the burn-in mode enable signals and a fourth pMOS transistor controlled by the inverted signals of the burn-in mode enable signals, a fifth CMOS transistor having a fifth pMOS transistor controlled by the burn-in mode enable signals and a fifth nMOS transistor controlled by the inverted signals of the burn-in mode enable signals, and a sixth CMOS transistor having a sixth nMOS transistor controlled by the burn-in mode enable signals and a sixth pMOS transistor controlled by the inverted signals of the burn-in mode enable signals.

At least the above and other features and advantages of the present invention may be realized by providing a burn-in test method for a semiconductor memory device, the method including loading a memory device having a memory cell array into a burn-in test apparatus, loading a burn-in program for performing a burn-in test into the burn-in test apparatus, writing a first data to the memory cell array, reading a second data stored in the memory cell array, performing a pass/fail decision to determine whether the second data has passed or failed based on an inverted logical value of the first data, unloading the burn-in program from the burn-in test apparatus, and unloading the memory device from the burn-in test apparatus.

At least one of the above and other features and advantages of the present invention may be realized by providing a burn-in test method for a semiconductor memory device, the method including loading a memory device having a memory cell array into a burn-in test apparatus, loading a burn-in program for performing a burn-in test into the burn-in test apparatus, inputting first external control signals suitable for a read state from the burn-in test apparatus to the memory device, writing a third data to the memory cell array, inputting second external control signals suitable for a write state from the burn-in test apparatus to the memory device, reading a fourth data stored in the memory cell array, performing a pass/fail decision to determine whether the fourth data has passed or failed based on a logical value of the third data, unloading the burn-in program from the burn-in test apparatus, and unloading the memory device from the burn-in test apparatus.

The above methods may further include, after performing the pass/fail decision step, comparing a read/write count of the writing of data and the reading of the data with a first or a second prescribed number, wherein, if the write/read count is smaller than the first or the second prescribed number, the steps from the writing of the data or the inputting of the first signal to the pass/fail decision step are repeated.

In the methods, the first or the second prescribed number may be three (3), and the writing of the data may have a first step and a third step writing a logical value “0” to the memory cell array and a second step writing a logical value “1” to the memory cell array.

In the method, the memory device may further include inverting logical values of input data or output data according to burn-in mode enable signals. Alternatively, the method may further include inverting the external control signals or the internal control signals according to burn-in mode enable signals.

The method may further include, after performing the pass/fail decision, providing a specific signal to a medium of display or alarm if the second data are failed or if the reading of the fourth data is failed.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a block diagram schematically illustrating a structure of a conventional memory device;

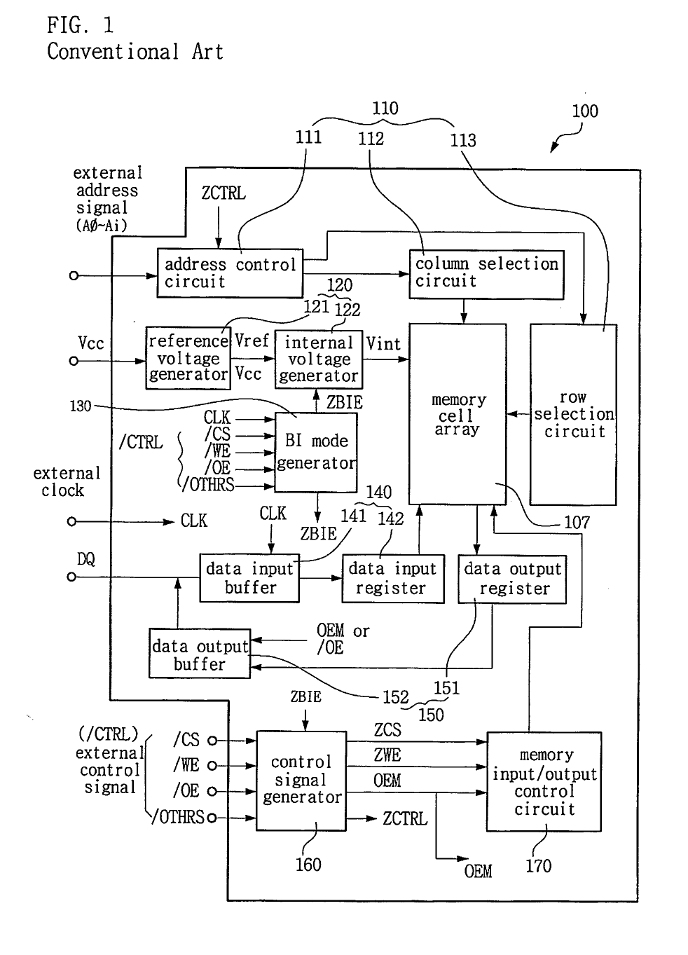

FIG. 2 is a graph illustrating a relation between an internal voltage and an external voltage;

FIG. 3 is a flow chart schematically illustrating a conventional burn-in test method for a memory device;

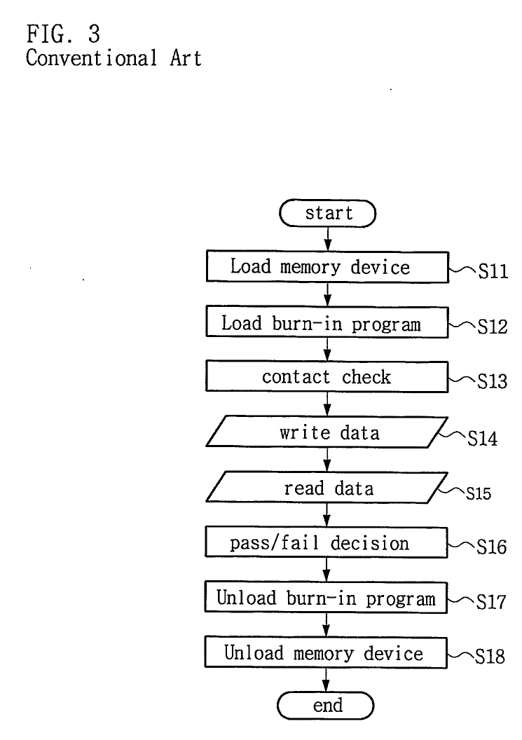

FIG. 4 is a diagram schematically illustrating a write and read data procedure in the conventional burn-in test method;

FIG. 5 is a block diagram schematically illustrating a structure of a memory device in accordance with a first exemplary embodiment of the present invention;

FIG. 6 is a flow chart schematically illustrating a burn-in test method for a memory device in accordance with the first exemplary embodiment of the present invention;

FIG. 7 is a diagram schematically illustrating a write and read data procedure in the burn-in test method in accordance with the first exemplary embodiment of the present invention;

FIG. 8 is a block diagram schematically illustrating a structure of a memory device in accordance with a second exemplary embodiment of the present invention;

FIG. 9 is a block diagram schematically illustrating a structure of a memory device in accordance with a third exemplary embodiment of the present invention;

FIG. 10 is a flow chart schematically illustrating a burn-in test method for a memory device in accordance with the third exemplary embodiment of the present invention;

FIG. 11 is a diagram schematically illustrating a write and read data procedure in the burn-in test method in accordance with the third exemplary embodiment of the present invention; and

FIG. 12 is a diagram schematically illustrating a write and read data procedure in the burn-in test method in accordance with the third exemplary embodiment of the present invention.

### DETAILED DESCRIPTION OF THE INVENTION

Korean Patent Application No. 2004-43531, filed on Jun. 14, 2004, in the Korean Intellectual Property Office, and entitled: “Semiconductor Memory Device and Burn-in Test Method Therefor,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals and characters refer to like elements throughout. In the context of the present invention, ordinal numbers are used to facilitate distinction between the various embodiments of the present invention and are not intended to suggest or imply the inclusion of other similar elements, e.g., a third transistor may be present in an embodiment of the present invention without a first or second transistor being provided in that embodiment.

### FIRST EXEMPLARY EMBODIMENT

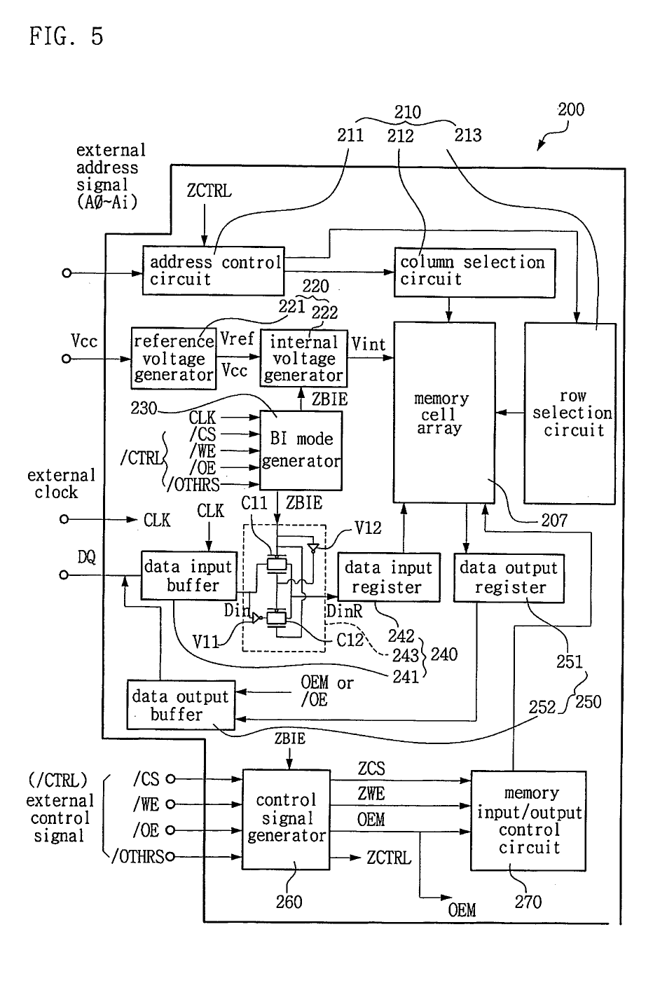

FIG. 5 is a block diagram schematically illustrating a structure of a memory device in accordance with a first exemplary embodiment of the present invention.

As shown in FIG. 5, the memory device 200 includes a memory cell array 207, an address control unit 210, an internal voltage generating unit 220, a burn-in (BI) mode generator 230, a data input unit 240, a data output unit 250, a control signal generator 260, and a memory input/output control circuit 270.

The memory cell array 207 has a large number of memory cells arranged in rows and columns as in a matrix.

The address control unit 210 includes an address control circuit 211, a column selection circuit 212, and a row selection circuit 213. The address control circuit 211 receives external address signals (A0˜-Ai) and then outputs column address signals and row address signals to the column selection circuit 212 and the row selection circuit 213, respectively, under the control of internal control signals (ZCTRL) produced in the control signal generator 260. The column selection circuit 212 and the row selection circuit 213 decode the column address signals and the row address signals, respectively, and then select a specific column line, e.g., a bit line, and a specific row line, e.g., a word line, in the memory cell array 207.

The internal voltage generating unit 220 includes a reference voltage generator 221 and an internal voltage generator 222. The reference voltage generator 221 generates a reference voltage (Vref) in the memory device 200. The internal voltage generator 222 generates an internal voltage (Vint) applied to the memory cell array 207.

The burn-in mode generator 230 receives external control signals (/CTRL), such as chip select signals (/CS), write enable signal (/WE), out enable signals (/OE) and other remaining signals (/OTHRS). Then, the burn-in mode generator 230 synchronizes and combines the external control signals (/CTRL) and thereby activates burn-in mode enable signals (ZBIE). Additionally, the burn-in mode generator 230 outputs the activated burn-in mode enable signals (ZBIE) to a first data switch circuit 243 in a case of a burn-in mode.

The external control signals (/CTRL) may include a variety of codes, such as J-TAG (joint test action group) vendor mode or MRS (mode resist set), by combining other remaining signals (/OTHRS). The remaining signals (/OTHRS) may depend upon the type of the memory device. For example, in a case of dynamic random access memory (DRAM), the remaining signals (/OTHRS) may have address control signals, such as row access strobe (/RAS) and column access strobe (/CAS).

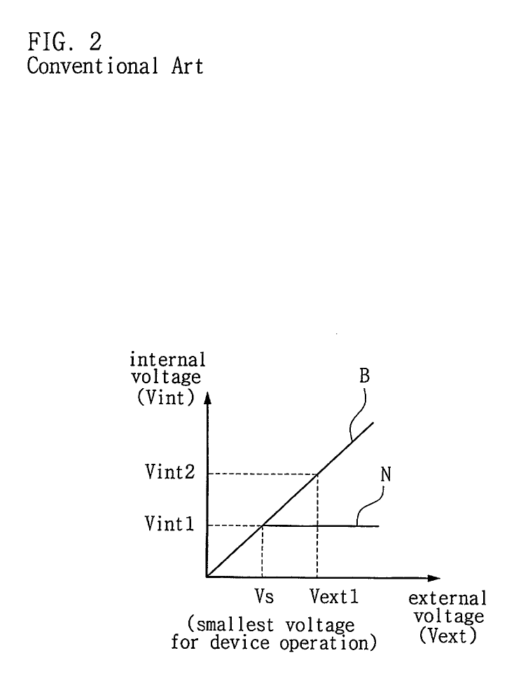

Referring to FIG. 5 and with reference back to FIG. 2, in a case of a normal operation state, in which the burn-in mode generator 230 does not activate burn-in mode enable signals (ZBIE), the memory device 200 is in a normal operation mode (N), in which the internal voltage generator 222 applies a uniform internal voltage (Vint1) to the memory cell array 207 when an external voltage (Vext) is above the smallest voltage (Vs) necessary for device operation. However, in a case of a burn-in state, in which the burn-in mode generator 230 outputs the activated burn-in mode enable signals (ZBIE) to the internal voltage generator 222, the memory device 200 is in a burn-in mode (B), in which the internal voltage generator 222 applies an internal voltage, rising in proportion to a rise in an external voltage, to the memory cell array 207.

Returning to FIG. 5, the data input unit 240 includes a data input buffer 241, the first data switch circuit 243, and a data input register 242. The data input buffer 241 receives data from data input/output terminals (DQ) and then outputs a first input data (Din) synchronized with clock signals (CLK).

The first data switch circuit 243 inverts the first input data (Din) into a second input data (DinR) when the burn-in mode enable signals (ZBIE) are activated. When the burn-in mode enable signals (ZBIE) are not activated, the first input data (Din) becomes the second input data (DinR), as it is, without being inverted.

The first data switch circuit 243 may include a first complementary metal oxide semiconductor (CMOS) transistor C11 and a second CMOS transistor C12. Furthermore, the first CMOS transistor C11 includes a first p-type MOS (pMOS) transistor controlled by the burn-in mode enable signals (ZBIE), and a first n-type MOS (nMOS) transistor controlled by the inverted signals of the burn-in mode enable signals (ZBIE). The second CMOS transistor C12 includes a second nMOS transistor controlled by the burn-in mode enable signals (ZBIE), and a second pMOS transistor controlled by the inverted signals of the burn-in mode enable signals (ZBIE).

The first data switch circuit 243 may further include a first inverter V11 for inverting the first input data Din, and a second inverter V12 for inverting the burn-in mode enable signals (ZBIE). When the burn-in mode enable signals (ZBIE) are activated, and therefore a burn-in mode voltage is applied to the memory cell array 207, the second input data (DinR) inverted from the first input data (Din) is output to the data input register 242, and finally stored in a selected memory cell of the memory cell array 207.

Alternatively, the first data switch circuit 243 may use another switching member, instead of the aforementioned CMOS transistors, that allows inverting data by the burn-in mode enable signals (ZBIE).

The data input register 242 outputs the second input data (DinR) to the selected memory cell of the memory cell array 207. When the second input data (DinR) is output, a writing driver circuit (not shown) may be used to write data in the selected memory cell under the control of internal control signals (ZCTRL) of the control signal generator 260.

The data output unit 250 includes a sens amp (not shown), a data output register 251, and a data output buffer 252. The sens amp amplifies data in the memory cell array 207. The data output register 251 receives amplified data and then outputs it to the data output buffer 252. The data output buffer 252 activates amplified data under the control of internal output enable signals (OEM) and outputs it to the data input/output terminals (DQ).

The control signal generator 260 receives the burn-in mode enable signals (ZBIE) as well as the external control signals (/CTRL), such as chip select signals (/CS), write enable signal (/WE), out enable signals (/OE) and other signals (/OTHRS). The control signal generator 260 then outputs internal control signals (ZCTRL), such as internal chip select signals (ZCS), internal input enable signals (ZWE) and internal output enable signals (OEM).

The memory input/output control circuit 270 determines, by receiving the internal control signals (ZCTRL), whether an operation state of the memory cell array 207 is a write state or a read state, and then outputs a specific signal to the memory cell array 207.

TABLE 1

| | ZWE (/WE) | OEM (/OE) | Write state | Read state |
|---|---|---|---|---|
| Case 1 | L | H | No | Yes |
| Case 2 | H | L | Yes | No |

For example, when the internal output enable signals (OEM) are enabled, i.e., logically on a high level, and the internal input enable signals (ZWE) are disabled, i.e., logically on a low level, as in case 1 of Table 1 above, the memory cell array 207 is in a read state. Alternatively, when the ZWE is enabled and the OEM is disabled, as in case 2, the memory cell array 207 is in a write state. Here, if the ZWE is enabled, the corresponding external signals /WE are activated. The same is the case in connection with the OEM and the /OE.

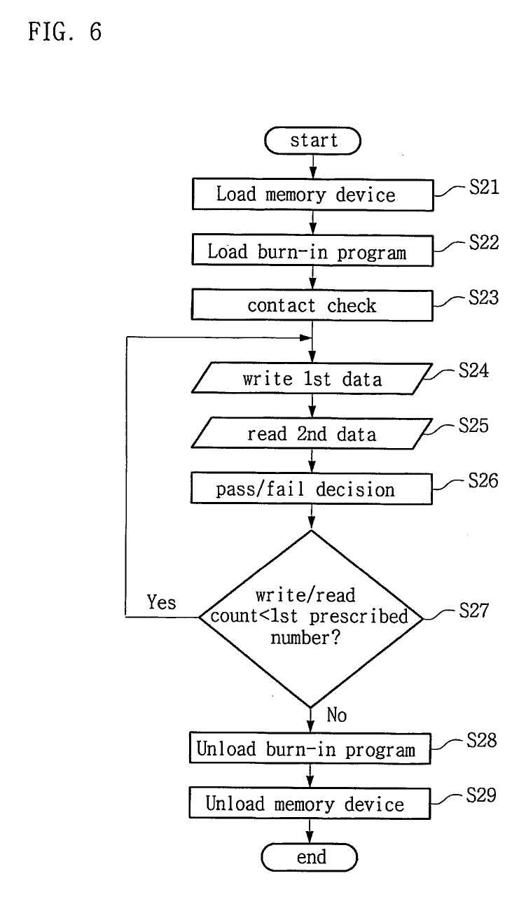

FIG. 6 is a flow chart schematically illustrating a burn-in test method for a memory device in accordance with the first exemplary embodiment of the present invention.

Referring to FIGS. 5 and 6, initially, in step S21, the memory device 200 including the memory cell array 207 is loaded into a burn-in test apparatus (not shown). The memory device 200 may be at a wafer level or a package level.

In step S22, a burn-in program for the burn-in test is loaded into the burn-in test apparatus. The burn-in program is a selected one suitable for the type of the memory device 200.

In step S23, a contact check is performed to ascertain whether the memory device 200 is properly loaded into the burn-in test apparatus and whether the burn-in program is fit for the loaded memory device 200.

In step S24, a write data operation is performed to write a first data to the memory cell array 207. The first data is represented as an arrangement of logical values “0” and “1”.

In step S25, a read data operation is performed to read a second data stored in the memory cell array 207. The second data is also represented as an arrangement of logical values “0” and “1”.

Thereafter, in step S26, a pass/fail decision is performed to determine whether the second data has passed or failed based on an inverted logical value of the first data.

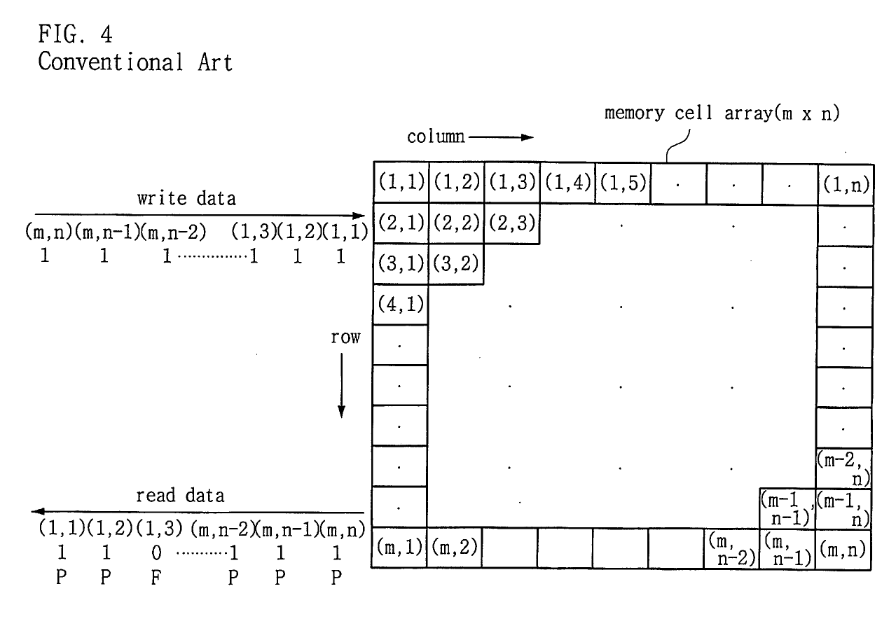

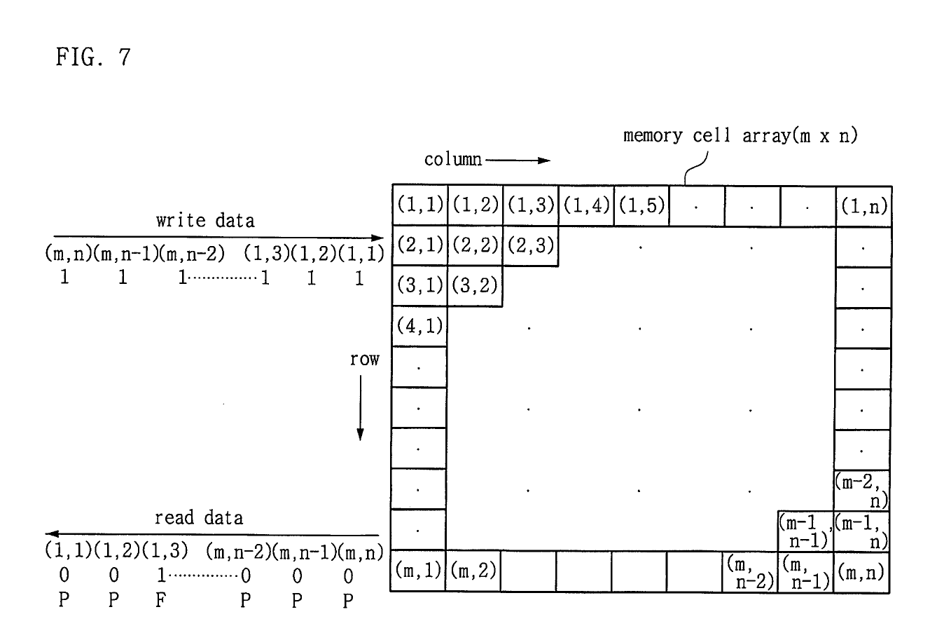

FIG. 7 is a diagram schematically illustrating a write and read data procedure in the burn-in test method in accordance with the first exemplary embodiment of the present invention. In FIG. 7, (m, n) represents an m-th row and an n-th column of the memory cell array. Rows and columns may correspond to word lines and bit lines, respectively, of the memory cell array, but not necessarily to the same word line or bit line. Although FIG. 4 illustrates a write and read data procedure performed in an order of (1, 1), (1, 2), (1, 3), . . . , another order such as (1, 1), (2, 1), (3, 1), . . . may be also possible.

As shown in FIG. 7, if a first data “1 ” is written during the write data step, i.e., step S24, and then a second data “0 ” is read during the read data step, i.e., step S25, the corresponding memory cell, e.g., cell (1,1), is determined to have passed (P). But, if a first data “l 1 ” is written and then a second data “1 ” is read, the corresponding memory cell, e.g., cell (1,3), is determined to have failed (F). Similarly, if write data is “0 ” and read data is “1 ”, the corresponding memory cell is determined to have passed (P). But, if write data is “0 ” and read data is also “0 ”, the corresponding memory cell is determined to have failed (F).

This result is made possible by the first data switch circuit 243 included in the memory device 200 and shown in FIG. 5. When the burn-in mode enable signals (ZBIE) are activated, the first input data (Din) is inverted. Therefore, the pass/fail decision should be made on the basis of an inverted logical value of the first input data (Din).

If all or almost all of the second data are deemed failed, the memory device 200 is not very likely to be in a normal operation mode, but rather, in a burn-in mode. If the burn-in mode enable signals (ZBIE) are not activated, data is not inverted in the first data switch circuit 243. Therefore, if all or almost all of the failure decisions are suddenly exhibited during the burn-in test, which was normally continuing, it may be concluded that the memory device 200 is in the normal operation mode. That is, it may be possible to determine whether the memory device 200 is in the burn-in mode or in the normal operation mode. Accordingly, if decisions about the second data are completely failures, it is necessary to inform a working engineer of the normal operation mode through a suitable medium of display or alarm, such as a monitor, a warning lamp, a speaker, and other similar device.

Returning to FIG. 6, after the pass/fail decision, in step S27, a write/read count is compared with a first prescribed number. If the write/read count is smaller than the first prescribed number, the aforementioned steps of the write data operation, the read data operation and the pass/fail decision, i.e., steps S24, S25 and S26, are repeated. The first prescribed number may be three (3), for example. In this case, the write and read data operations are each performed three (3) times, respectively. Further, the write data step may include a first step and a third step writing a logical value “0” and a second step writing a logical value “1”.

When the write/read count reaches the first prescribed number, in step S28, the burn-in program is unloaded from the apparatus, and then, in step S29, the memory device is also unloaded. In addition, if a fail decision is made in the above-described pass/fail decision step, i.e., step S26, both unloading steps, i.e., steps S28 and S29, may be immediately performed and the comparing step, i.e., step S27, may be skipped. Moreover, pass/fail decision values about the memory cells may be stored as data, and further, such data may be used to find defective cells in a subsequent repairing process.

### SECOND EXEMPLARY EMBODIMENT

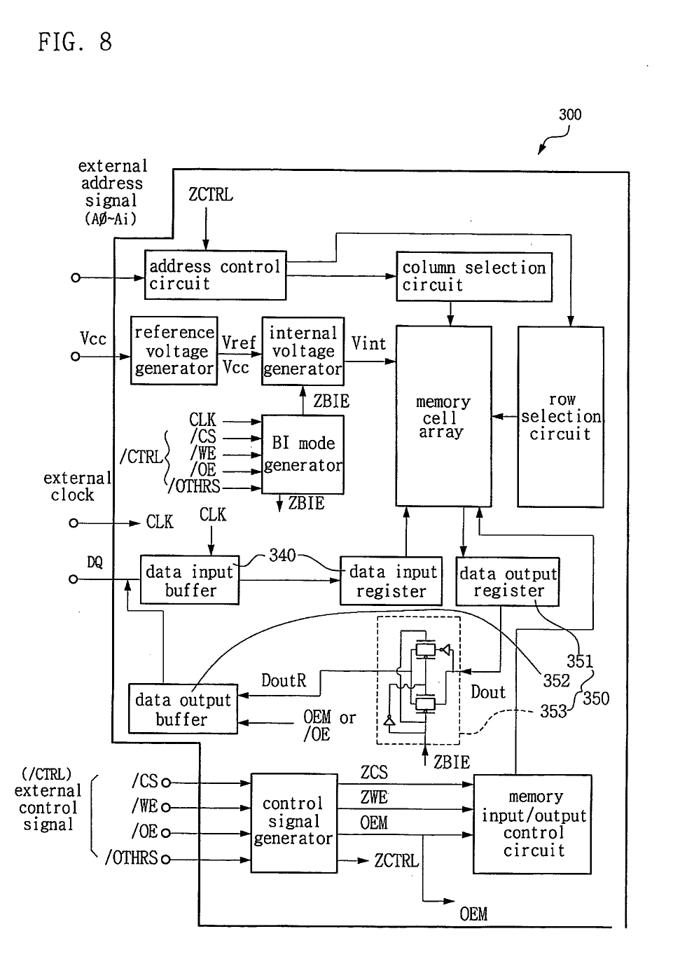

FIG. 8 is a block diagram schematically illustrating a structure of a memory device in accordance with a second exemplary embodiment of the present invention.

As shown in FIG. 8, the memory device 300 of this embodiment has substantially the same structure as that of the above-described first embodiment, except that a data input unit 340 omits the aforementioned first data switch circuit 243 shown in FIG. 5, and a data output unit 350 includes a second data switch circuit 353. Accordingly, descriptions of common elements will not be repeated.

The second data switch circuit 353 of the data output unit 350 is interposed between a data output register 351 and a data output buffer 352. The data output register 351 and the data output buffer 352 are the same elements as previously described in connection with the first embodiment. The second data switch circuit 353 has the same structure as that of the first data switch circuit 243 in the first embodiment, and has similar function to that of the first data switch circuit 243 in the first embodiment. More specifically, the second data switch circuit 353 inverts first output data (Dout) produced by the data output register 351 and produces a second output data (DoutR) when the burn-in mode enable signals (ZBIE) are activated. When the burn-in mode enable signals (ZBIE) are not activated, the first output data (Dout) becomes the second output data (DoutR), as it is, without being inverted.

While the above-described first embodiment is a case where data input is inverted, the second embodiment is a case where data output is inverted. Accordingly, there is little difference between these embodiments, considered in relation to the memory device as a whole. Accordingly, a process of making the pass/fail decision is also the same as in the first embodiment.

### THIRD EXEMPLARY EMBODIMENT

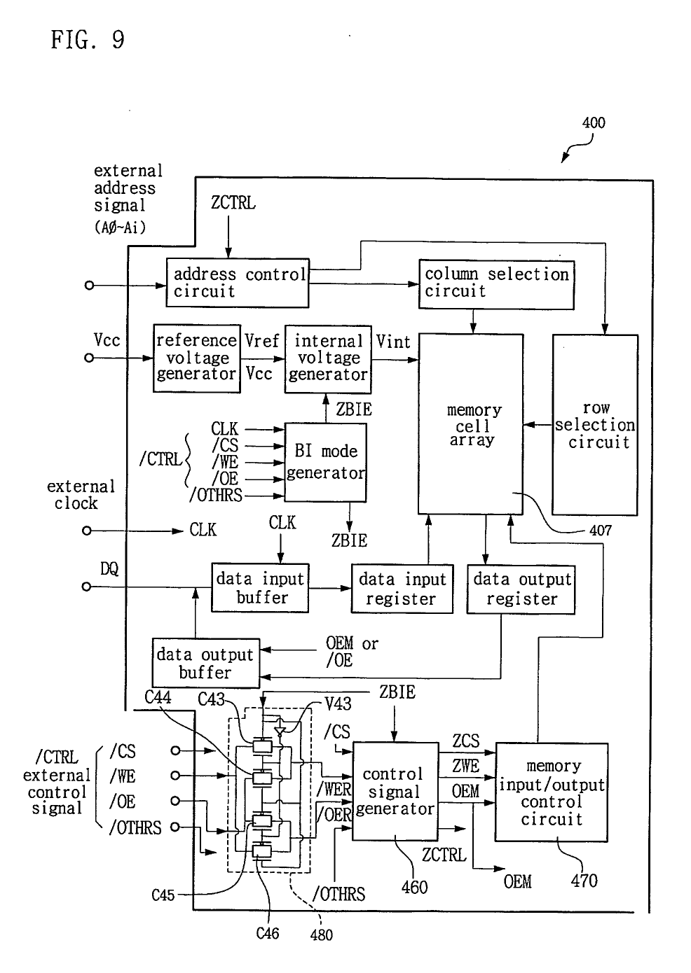

FIG. 9 is a block diagram schematically illustrating a structure of a memory device in accordance with a third exemplary embodiment of the present invention.

As shown in FIG. 9, the memory device 400 of the third embodiment has substantially the same structure as that of the above-described first embodiment, except in connection with a control signal generator 460, a memory input/output control circuit 470, and a control signal switch circuit 480. Accordingly, descriptions of common elements will not be repeated.

The control signal switch circuit 480 inverts external control signals (/CTRL), such as write enable signal (/WE) and out enable signals (/OE), when the burn-in mode enable signals (ZBIE) are activated. For example, when the memory device 400 receives /WE of “H” and /OE of “L”, these external control signals are inverted into “L” and “H”, respectively, after passing through the control signal switch circuit 480 when the burn-in mode enable signals (ZBIE) are activated. This is the same as write/read states of the memory cell being changed, that is, from case 1 to case 2, and vice versa, as shown in Table 1 above. When the burn-in mode enable signals (ZBIE) are not activated, however, the write/read states are not changed.

The control signal switch circuit 480 may include third through sixth CMOS transistors C43 - C46. The third CMOS transistor C43 includes a third pMOS transistor controlled by the burn-in mode enable signals (ZBIE), and a third nMOS transistor controlled by the inverted signals of the burn-in mode enable signals (ZBIE). The fourth CMOS transistor C44 includes a fourth nMOS transistor controlled by the burn-in mode enable signals (ZBIE), and a fourth pMOS transistor controlled by the inverted signals of the burn-in mode enable signals (ZBIE). The fifth CMOS transistor C45 includes a fifth pMOS transistor controlled by the burn-in mode enable signals (ZBIE), and a fifth nMOS transistor controlled by the inverted signals of the burn-in mode enable signals (ZBIE). The sixth CMOS transistor C46 includes a sixth nMOS transistor controlled by the burn-in mode enable signals (ZBIE), and a sixth pMOS transistor controlled by the inverted signals of the burn-in mode enable signals (ZBIE).

The control signal switch circuit 480 may further include a third inverter V43 for inverting the burn-in mode enable signals (ZBIE). Alternatively, the control signal switch circuit 480 may be located between the control signal generator 460 and the memory input/output control circuit 470, and therefore inverts the internal control signals (ZCTRL). As a further alternative, the control signal switch circuit 480 may use another switching member, instead of the aforementioned CMOS transistors, that allows inverting control signals by the burn-in mode enable signals (ZBIE).

The control signal generator 460 receives the burn-in mode enable signals (ZBIE) and the external control signals (/CTRL), and then outputs internal control signals (ZCTRL), such as internal chip select signals (ZCS), internal input enable signals (ZWE) and internal output enable signals (OEM).

The memory input/output control circuit 470 determines, by receiving the internal control signals (ZCTRL), whether an operation state of the memory cell array 407 is a write state or a read state, and then outputs a specific signal to the memory cell array 407.

TABLE 2

| | Before switch circuit | | | After switch circuit | | |
|---|---|---|---|---|---|---|
| | (Outside of | | | (Inside of device) (ZBIE activated) | | |
| | device) | | | /WER | /OER | |
| | /WE | /OE | State | (ZWE) | (OEM) | State |
| Case 3 | L | H | Read state | H | L | Write state |
| Case 4 | H | L | Write state | L | H | Read state |

For example, as in case 3 of Table 2, when the out enable signals (/OE) are enabled, i.e., logically on a high level, and the write enable signal (NVE) is disabled, i.e., logically on a low level, before passing through the control signal switch circuit 480, the memory cell array 407 is in a read state. However, after passing through the control signal switch circuit 480 when the burn-in mode enable signals (ZBIE) are activated, inverted external input enable signals (/WER) or the internal input enable signals (ZWE) are inverted into “H”, and inverted external output enable signals (/OER) or the internal output enable signals (OEM) are inverted into “L”. Case 4 of Table 2 is opposite to case 3.

Therefore, with the ZBIE activated, if the burn-in test apparatus performs a read data operation after inputting external control signals suitable for a read state to the memory device, no operation of read data is performed in the memory device since the memory device is actually in a write state. The same is true under the opposite circumstances. So, for the purpose of performing a write data step, the burn-in test apparatus should input external control signals suitable for a read state to the memory device.

However, if the ZBIE is not activated, inversion of the external control signals does not occur. So, even if inverted signals are input in consideration of the inversion of external control signals, the memory device with the ZBIE not activated is in no operation state. It is therefore concluded that the memory device is in the normal operation mode. That is, it may be possible to determine whether the memory device is in the burn-in mode or in the normal operation mode.

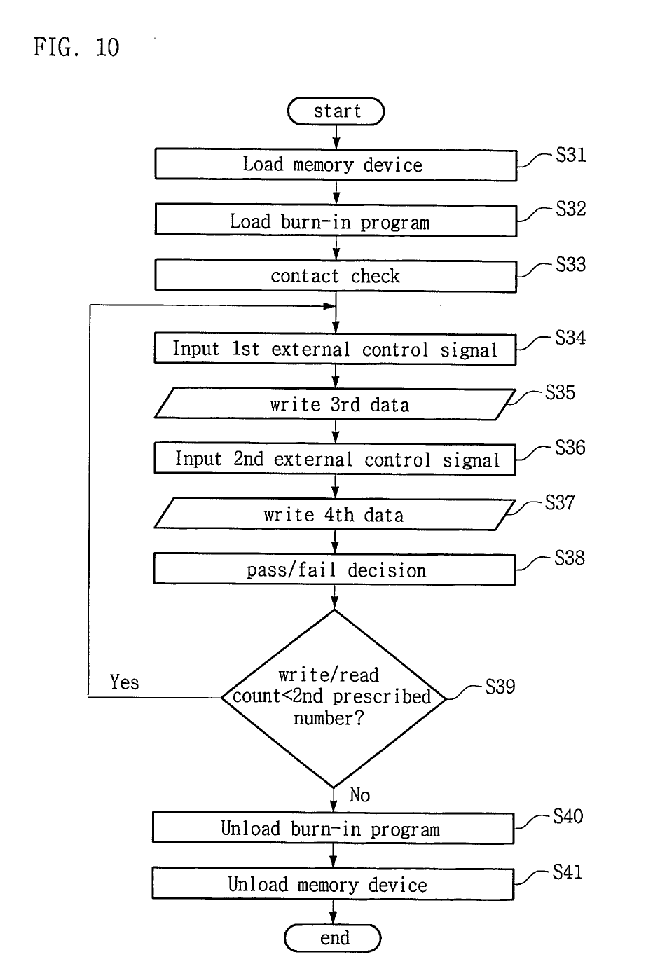

FIG. 10 is a flow chart schematically illustrating a burn-in test method for a memory device in accordance with the third exemplary embodiment of the present invention.

Referring to FIGS. 9 and 10, initially, in step S31, the memory device 400 including the memory cell array 407 is loaded into a burn-in test apparatus (not shown). In step S32, a burn-in program for the burn-in test is loaded into the burn-in test apparatus. In step S33, a contact check is performed.

In step S34, first external control signals suitable for a read state are input from the apparatus to the memory device 400. For example, the first external control signals are the NVE of “L” and the /OE of “H” as shown in case 3 of Table 2 above.

In step S35, a write data operation is performed to write a third data to the memory cell array 407. The third data is represented as an arrangement of logical values “0” and “1”. Here, as shown in case 3 of Table 2 above, the activated ZBIE offers a write state to the memory cell array, so the write data operation is normally performed. However, the non-activated ZBIE offers a read state to the memory cell array, so the write data operation is not performed and thereby the device is in no operation state.

In step S36, second external control signals suitable for a write state are input from the apparatus to the memory device 400. For example, the second external control signals are the /WE of “H” and the /OE of “L” as shown in case 4 of Table 2 above.

In step S37, a read data operation is performed to read a fourth data stored in the memory cell array 407. The fourth data is also represented as an arrangement of logical values “0” and “1”. Here, as shown in case 4 of Table 2 above, the activated ZBIE offers a read state to the memory cell array, so the read data step is normally performed. However, the non-activated ZBIE offers a write state to the memory cell array, so the read data step is not performed and thereby the device is in no operation state.

Thereafter, in step S38, a pass/fail decision is performed to determine whether the fourth data has passed or failed based on a logical value of the third data.

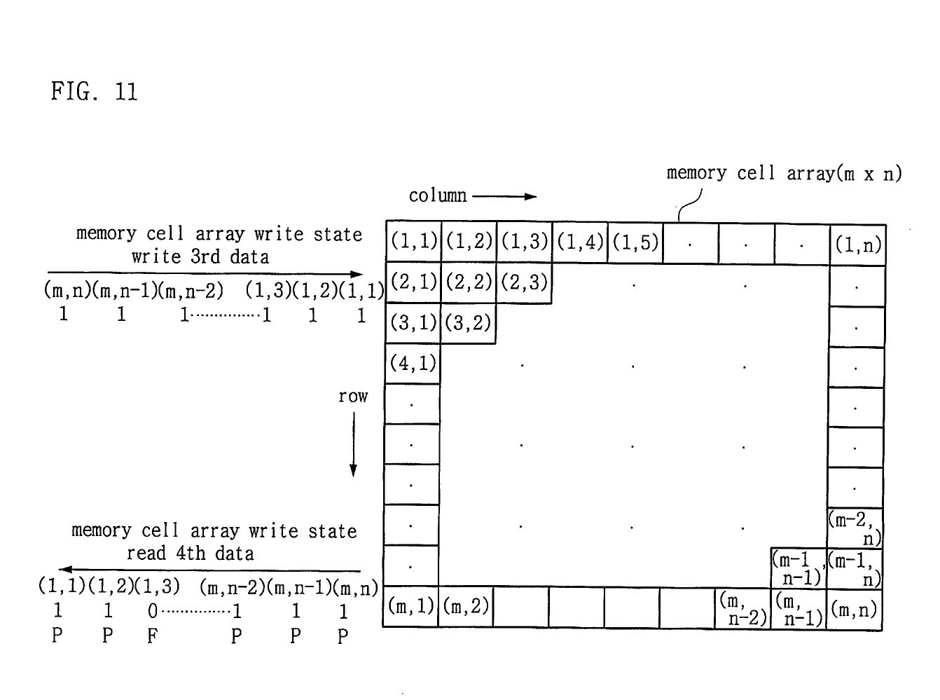

FIG. 11 is a diagram schematically illustrating a write and read data procedure in the burn-in test method in accordance with the third exemplary embodiment of the present invention.

As shown in FIG. 11, if a third data “1 ” is written during the write data step, i.e., step S35, and then a fourth data “1 ” is read during the read data step, i.e., step S37, the corresponding memory cell, e.g., cell (1,1), is determined to have passed (P). But, if a third data “1 ” is written and then a fourth data “0 ” is read, the corresponding memory cell, e.g., cell (1,3), is determined to have failed (F). Similarly, if a write data is “0 ” and a read data is also “0 ”, the corresponding memory cell is determined to have passed (P). But, if a write data is “0 ” and read data is “1 ”, the corresponding memory cell is determined to have failed (F).

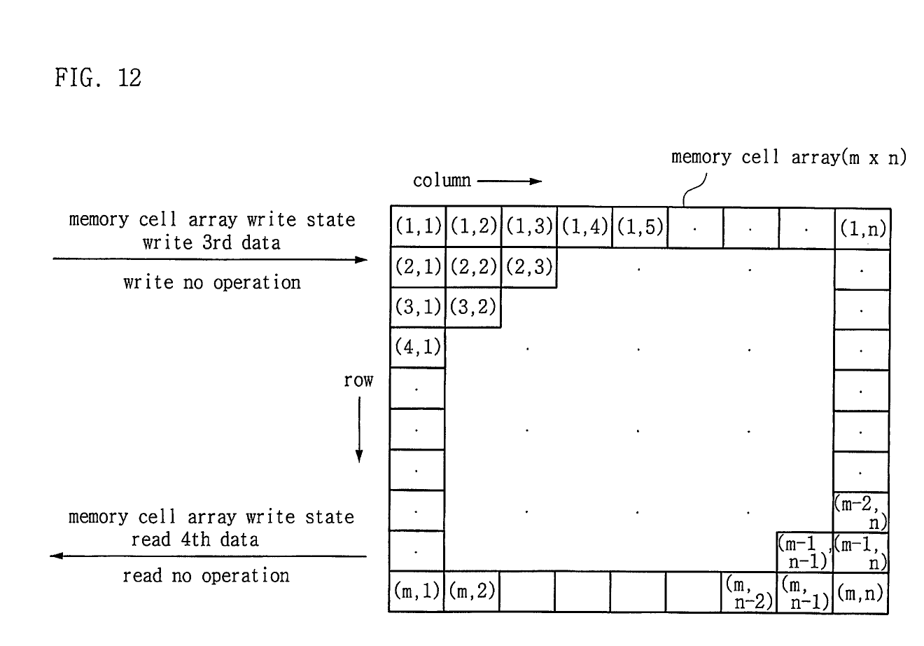

FIG. 12 is a diagram schematically illustrating a write and read data procedure in the burn-in test method in accordance with the third exemplary embodiment of the present invention.

As shown in FIG. 12, in a case of non-activated burn-in mode enable signals (ZBIE), though a third data “1 ” is input as write data during the write data step, i.e., step S35, the write data operation is not made. Similarly, the read data operation is also not performed during the read data step, i.e., step S37.

Returning to FIG. 10, after the pass/fail decision, in step S39, a write/read count is compared with a second prescribed number. If the write/read count is smaller than the second prescribed number, the aforementioned steps from S34 through S38 are repeated. The second prescribed number may be three (3), for example. In this case, the write data and read data operations are each performed three (3) times. Further, the write data step may include a first step and a third step writing a logical value “0” and a second step writing a logical value “1”.

When the write/read count reaches the second prescribed number, in step S40, the burn-in program is unloaded from the apparatus, and then, in step S41, the memory device is also unloaded. In addition, if a fail decision is made in the above-described pass/fail decision step, i.e., step S38, both unloading steps, i.e., steps S40 and S41, may be immediately performed and the comparing step, i.e., step S39, may be skipped.

In the present invention, the first or the second external control signals for a read state or a write state are not limited to the aforementioned specific signals, and further, may be established differently according to the type of the burn-in test apparatus or the working engineer.

Although the above-described embodiments are cases in which the memory device includes the first data switch circuit, the second data switch circuit, or the control signal switch circuit, such a circuit may be included in the burn-in test apparatus and thereby the burn-in mode enable signals may be produced from the apparatus. In such a case, conventional memory devices may also be applied to the present invention.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1-9. (canceled)

10. A bum-in test method for a semiconductor memory device, the method comprising:
loading a memory device having a memory cell array into a bum-in test apparatus;
loading a burn-in program for performing a bum-in test into the bum-in test apparatus;
writing a first data to the memory cell array;
reading a second data stored in the memory cell array;
performing a pass/fail decision to determine whether the second data has passed or failed based on an inverted logical value of the first data;
unloading the burn-in program from the burn-in test apparatus; and
unloading the memory device from the burn-in test apparatus.

11. The method as claimed in claim 10, further comprising:
after performing the pass/fail decision, comparing a read/write count of the writing of the first data and the reading of the second data with a first prescribed number,
wherein, if the write/read count is smaller than the first prescribed number, the writing of the first data, the reading of the second data, and the pass/fail decision are repeated.

12. The method as claimed in claim 11, wherein the first prescribed number is three (3), and writing the first data includes a first step and a third step writing a logical value “0” to the memory cell array and a second step writing a logical value “1” to the memory cell array.

13. The method as claimed in claim 10, further comprising inverting logical values of input data or output data according to burn-in mode enable signals.

14. The method as claimed in claim 10, further comprising:
providing a specific signal to a medium of display or alarm if the second data has failed, after performing the pass/fail decision.

15. A burn-in test method for a semiconductor memory device, the method comprising:
loading a memory device having a memory cell array into a burn-in test apparatus;
loading a burn-in program for performing a burn-in test into the burn-in test apparatus;
inputting first external control signals suitable for a read state from the burn-in test apparatus to the memory device;
writing a third data to the memory cell array;
inputting second external control signals suitable for a write state from the burn-in test apparatus to the memory device;
reading a fourth data stored in the memory cell array;
performing a pass/fail decision to determine whether the fourth data has passed or failed based on a logical value of the third data;
unloading the burn-in program from the burn-in test apparatus; and
unloading the memory device from the burn-in test apparatus.

16. The method as claimed in claim 15, further comprising:
after performing the pass/fail decision, comparing a read/write count of the writing of the third data and the reading of the fourth data with a second prescribed number,
wherein, if the write/read count is smaller than the second prescribed number, the inputting of the first external control signals, the writing of the third data, the inputting of the second external control signals, the reading of the fourth data, and the performing of the pass/fail decision are repeated.

17. The method as claimed in claim 16, wherein the second prescribed number is three (3), and the writing of the third data includes a first step and a third step writing a logical value “0” to the memory cell array and a second step writing a logical value “1” to the memory cell array.

18. The method as claimed in claim 15, further comprising inverting the external control signals or the internal control signals according to burn-in mode enable signals.

19. The method as claimed in claim 15, further comprising:
providing a specific signal to a medium of display or alarm if the fourth data has failed, after performing the pass/fail decision.
